(19) United States
(12) Patent Application Publication
(10) Pub. No.: US 2022/0285231 A1
(43) Pub. Date: Sep. 8, 2022

(54) SEMICONDUCTOR ELEMENT CHARACTERISTIC VALUE ESTIMATION METHOD AND SEMICONDUCTOR ELEMENT CHARACTERISTIC VALUE ESTIMATION SYSTEM

(71) Applicant: SEMICONDUCTOR ENERGY LABORATORY CO., LTD., Atsugi-shi, Kanagawa-ken (JP)

(72) Inventors: Junpei MOMO, Sagamihara, Kanagawa (JP); Tatsuya OKANO, Isehara, Kanagawa (JP)

(21) Appl. No.: 17/624,936

(22) PCT Filed: Jun. 30, 2020
(86) PCT No.: PCT/IB2020/056150

§ 371 Date: Jan. 5, 2022

(30) Foreign Application Priority Data
Jul. 12, 2019 (JP) 2019-130206

(51) Int. Cl. H01L 21/66; G05B 19/418

(52) U.S. Cl. CPC H01L 22/20; G05B 19/41875; G05B 2219/45031

(57) ABSTRACT

A semiconductor element characteristic value estimation system is provided. The semiconductor element characteristic value estimation system includes an input portion, a database, and a processing portion. A first step list, a second step list, and a characteristic value of a semiconductor element are input to the input portion. The database has a function of storing a group of step lists and a group of characteristic values of semiconductor elements. The processing portion has a function of performing comparison between two step lists selected from the first step list and the group of step lists; a function of performing a test using two or more characteristic values of semiconductor elements selected from the characteristic value of the semiconductor element and the group of characteristic values of the semiconductor elements; a function of performing regression analysis of parameters for a step and two or more characteristic values of semiconductor elements selected from the characteristic value of the semiconductor element and the group of characteristic values of the semiconductor elements; and a function of estimating a characteristic value of a semiconductor element from the second step list.

### TECHNICAL FIELD

One embodiment of the present invention relates to a method for estimating a characteristic value of a semiconductor element. Another embodiment of the present invention relates to a system which estimates a characteristic value of a semiconductor element.

Note that a semiconductor element in this specification and the like refers to an element that can operate by utilizing semiconductor characteristics. Examples of the semiconductor element are semiconductor elements such as a transistor, a diode, a light-emitting element, and a light-receiving element. Other examples of the semiconductor element are passive elements such as a capacitor, a resistor, and an inductor, which are formed using a conductive film, an insulating film, or the like. Still another example of the semiconductor element is a semiconductor device provided with a circuit including a semiconductor element or a passive element.

### BACKGROUND ART

In recent years, a novel semiconductor element has been developed to resolve an issue such as an increase in computational complexity or an increase in power consumption, in a field using artificial intelligence (AI), a robotic field, or a field needing high power energy for power ICs or the like. Integrated circuits demanded by markets or semiconductor elements used in the integrated circuits have become more complicated; meanwhile, an early startup of integrated circuits having novel functions has been demanded. For the process design, device design or circuit design in the development of semiconductor elements, knowledge, know-how, experience, or the like of skilled engineers is required.

In recent years, a method for optimizing the manufacturing process, a method for estimating device characteristics, and the like have been proposed regarding semiconductor devices. Patent Document 1 discloses a method of calculating an image feature value from a SEM image of a cross-sectional pattern of a semiconductor device and estimating device characteristics of an evaluation target pattern from the correspondence between the image feature value and device characteristics.

### REFERENCE

### Patent Document

[Patent Document 1] Japanese Published Patent Application No. 2007-129059

### SUMMARY OF THE INVENTION

### Problems to be Solved by the Invention

A manufacturing process of a semiconductor element involves many steps to complete the semiconductor element and there are also wide-ranging kinds of steps and processing conditions. Therefore, it is difficult to verify the step dependency of the characteristic value which is calculated from the electrical characteristics of the semiconductor element (the characteristic value is simply referred to as the characteristic value of the semiconductor element in some cases) or the like. Furthermore, enormous effort is required to compare the steps and the characteristic value of a newly prototyped semiconductor element with those of a previously prototyped semiconductor element.

With conventional techniques, comparing the manufacturing process of a semiconductor element involving a large number of steps with the manufacturing process of a previously prototyped semiconductor element is difficult. In addition, finding a feature step of a newly prototyped semiconductor element is also difficult.

In view of the foregoing, an object of one embodiment of the present invention is to provide a method for estimating a characteristic value of a semiconductor element to be prototyped. Another object of one embodiment of the present invention is to provide a system which estimates a characteristic value of a semiconductor element to be prototyped. Another object of one embodiment of the present invention is to provide a system which automatically compares steps and a characteristic value of a semiconductor element prototyped this time with those of a previously prototyped semiconductor element.

Note that the description of these objects does not preclude the existence of other objects. One embodiment of the present invention does not have to achieve all these objects. Other objects are apparent from and can be derived from the description of the specification, the drawings, the claims, and the like.

### Means for Solving the Problems

One embodiment of the present invention is a semiconductor element characteristic value estimation system including an input portion, a database, and a processing portion. A first step list, a second step list, and a characteristic value of a semiconductor element are input to the input portion. The database has a function of storing a group of step lists and a group of characteristic values of semiconductor elements. The processing portion has a function of performing comparison between two step lists selected from the first step list and the group of step lists, a function of performing a test using two or more characteristic values of semiconductor elements selected from the characteristic value of the semiconductor element and the group of characteristic values of the semiconductor elements, a function of performing regression analysis of parameters for a step and two or more characteristic values of semiconductor elements selected from the characteristic value of the semiconductor element and the group of characteristic values of the semiconductor elements, and a function of estimating a characteristic value of a semiconductor element from the second step list.

In the above-described semiconductor element characteristic value estimation system, a diff algorithm is preferably used in the comparison. In the test, a t-test is preferably used as a test using two characteristic values of semiconductor elements and a nonparametric test is preferably used as a test using three or more characteristic values of semiconductor elements.

In the above-described semiconductor element characteristic value estimation system, the database preferably includes a first memory portion and a second memory portion. The first memory portion preferably has a function of storing the group of step lists. The second memory portion preferably has a function of storing the group of characteristic values of the semiconductor elements.

In the above-described semiconductor element characteristic value estimation system, the processing portion preferably includes a first processing portion having a function of performing the comparison, a second processing portion having a function of performing the test, a third processing portion having a function of performing the regression analysis, and a fourth processing portion having a function of estimating a characteristic value of a semiconductor element from the second step list.

In the above-described semiconductor element characteristic value estimation system, the characteristic value of the semiconductor element estimated by the processing portion is preferably one or more of a threshold voltage, a subthreshold swing value, an on-state current, and a field-effect mobility.

Another embodiment of the present invention is a semiconductor element characteristic value estimation method which includes a first step of inputting a first step list included in a first lot and a characteristic value of a first semiconductor element manufactured in accordance with the first step list; a second step of collecting a second step list whose degree of similarity to the first step list is higher than or equal to a certain level from a group of step lists; a third step of performing a test using the characteristic value of the first semiconductor element and a characteristic value of a second semiconductor element manufactured in accordance with the second step list; a fourth step of performing, among a first plurality of semiconductor elements manufactured in accordance with a first plurality of step lists included in the first lot, analysis of variance on characteristic values of the first plurality of semiconductor elements and comparison of the first plurality of step lists and recording whether a step which is different among the first plurality of step lists influences the characteristic values of the first plurality of semiconductor elements; a fifth step of collecting a third step list whose degree of similarity to each of the first plurality of step lists is higher than or equal to a certain level from the group of step lists; a sixth step of performing regression analysis of parameters for a step influencing the characteristic values of the first plurality of semiconductor elements and a characteristic value of a third semiconductor element manufactured in accordance with the third step list; and a seventh step of estimating, from a second plurality of step lists included in a second lot, characteristic values of a second plurality of semiconductor elements manufactured in accordance with the second plurality of step lists before the second plurality of semiconductor elements are manufactured.

In the above-described semiconductor element characteristic value estimation method, data is preferably output in the case where there is a significant difference between the characteristic value of the first semiconductor element and the characteristic value of the second semiconductor element in the test performed in the third step.

### Effect of the Invention

With one embodiment of the present invention, a method for estimating a characteristic value of a semiconductor element to be prototyped can be provided. With one embodiment of the present invention, a system which estimates a characteristic value of a semiconductor element to be prototyped can be provided. With one embodiment of the present invention, a system which automatically compares steps and a characteristic value of a semiconductor element prototyped this time with those of a previously prototyped semiconductor element can be provided.

Note that the effects of one embodiment of the present invention are not limited to the effects listed above. The effects listed above do not preclude the existence of other effects. The other effects are effects that are not described in this section and will be described below. The effects not described in this section are derived from the description of the specification, the drawings, and the like and can be extracted as appropriate from these descriptions by those skilled in the art. Note that one embodiment of the present invention is to have at least one of the effects listed above and/or the other effects. Accordingly, depending on the case, one embodiment of the present invention does not have the effects listed above in some cases.

### BRIEF DESCRIPTION OF THE DRAWINGS

FIG. 1 is a flow chart illustrating an example of a method for estimating a characteristic value of a semiconductor element.

FIG. 2A is a diagram illustrating a structure example of a lot. FIG. 2B is a diagram illustrating a characteristic value.

FIG. 3 is a diagram illustrating the example of the method for estimating a characteristic value of a semiconductor element.

FIG. 4 is a diagram illustrating the example of the method for estimating a characteristic value of a semiconductor element.

FIG. 5 is a diagram illustrating the example of the method for estimating a characteristic value of a semiconductor element.

FIG. 6 is a diagram illustrating the example of the method for estimating a characteristic value of a semiconductor element.

FIG. 7 is a diagram illustrating the example of the method for estimating a characteristic value of a semiconductor element.

FIG. 8 is a diagram illustrating the example of the method for estimating a characteristic value of a semiconductor element.

FIG. 9 is a diagram illustrating a structure example of a system.

FIG. 10 is a diagram illustrating a structure example of the system.

FIG. 11 is a diagram illustrating a structure example of the system.

FIG. 12 is a diagram illustrating a structure example of the system.

FIG. 13 is a diagram illustrating a computer device.

### MODE FOR CARRYING OUT THE INVENTION

Embodiment is described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be interpreted as being limited to the description of the embodiment below.

Note that in the structures of the invention described below, the same portions or portions having similar functions are denoted by the same reference numerals in different drawings, and description thereof is not repeated. Furthermore, the same hatch pattern is used for the portions having similar functions, and the portions are not especially denoted by reference numerals in some cases.

In addition, the position, size, range, or the like of each structure shown in drawings does not represent the actual position, size, range, or the like in some cases for easy understanding. Therefore, the disclosed invention is not necessarily limited to the position, size, range, or the like disclosed in the drawings.

Furthermore, it is noted that ordinal numbers such as “first”, “second”, and “third” used in this specification are used in order to avoid confusion among components, and the terms do not limit the components numerically.

### Embodiment

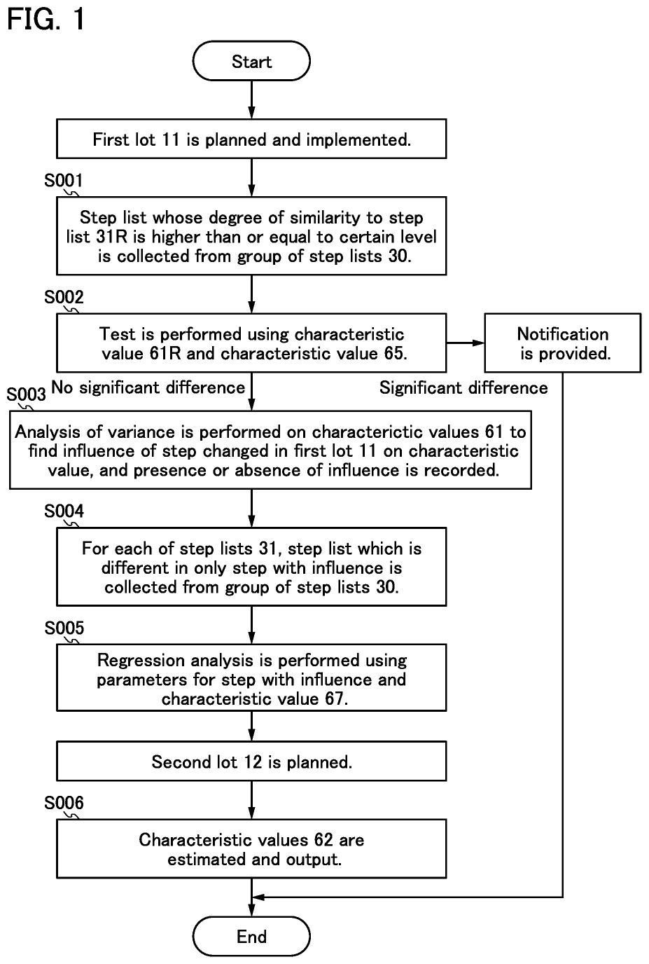

In this embodiment, a method for estimating a characteristic value of a semiconductor element (a semiconductor element characteristic value estimation method) and a system which estimates a characteristic value of a semiconductor element (a semiconductor element characteristic value estimation system), which are embodiments of the present invention, are described with reference to FIG. 1 to FIG. 13.

<Procedure>

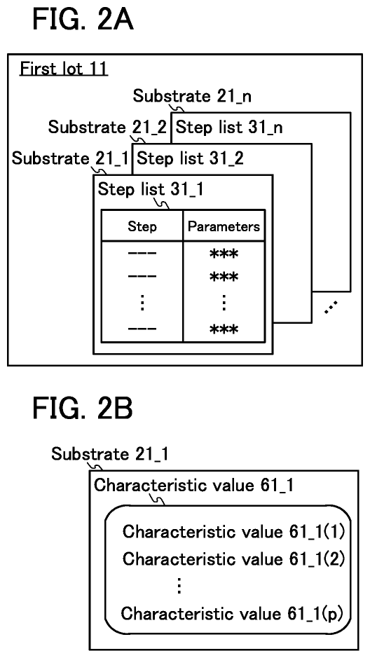

In this section, an example of the method for estimating a characteristic value of a semiconductor element is described with reference to FIG. 1, FIG. 2A, and FIG. 2B.

FIG. 1 is a flow chart illustrating the example of the method for estimating a characteristic value of a semiconductor element. As illustrated in FIG. 1, the method for estimating a characteristic value of a semiconductor element includes Step S001 to Step S006. Note that before each of Step S001 and Step S006, the user performs a task. Although described later, the task performed by the user before Step S001 may be omitted in some cases. Note that in this specification, “user” refers to a user of one embodiment of the present invention, a practitioner of one embodiment of the present invention, a planner of a lot, a practitioner of a lot, and the like.

First, the task performed by the user before Step S001 is described.

The user plans a first lot 11. Note that the first lot 11 is a lot planned before Step S001 illustrated in FIG. 1.

[First Lot 11]

Here, a structure of the first lot 11 is described with reference to FIG. 2A.

A lot refers to a minimum unit of products in producing the same kind of products. A lot can be regarded as the number of prototyped products in prototyping a product. For example, in the case of manufacturing a product including a semiconductor element, implementing one lot enables one or more products including a semiconductor element to be manufactured.

One or more substrates are prepared for the lot. In addition, a step list for manufacturing a product including a semiconductor element is prepared for each of the substrates. In the step list, a plurality of steps for manufacturing a product including a semiconductor element are set in the order of manufacturing steps and processing conditions are designated for each of the steps.

In the case of producing products including a semiconductor element, the step list prepared for each substrate in a single lot is the same. Meanwhile, in the case of prototyping semiconductor elements or products including a semiconductor element, the step list prepared for each substrate in a single lot is different in part of the steps in some cases. In this embodiment, a case of prototyping semiconductor elements is assumed. Furthermore, manufacturing a plurality of semiconductor elements over a substrate in accordance with a step list prepared for the substrate is assumed. Thus, in the following description, a plurality of semiconductor elements manufactured over a single substrate are expressed as a group of semiconductor elements or simply semiconductor elements in some cases.

“Planning a lot” refers to creation of a step list for each of the substrates in the lot.

FIG. 2A is a diagram illustrating a structure example of the first lot 11. As illustrated in FIG. 2A, a substrate 21_1 to a substrate 21_n (n is a natural number) are prepared for the first lot 11. The substrate 21_1 to the substrate 21_n are collectively referred to as substrates 21 in some cases below.

Note that an ID is assigned to each of the substrates. Here, the ID assigned to the substrate is expressed as a substrate ID.

As illustrated in FIG. 2A, a step list 31_1 to a step list 31_n are prepared for the substrate 21_1 to the substrate 21_n, respectively. The step list 31_1 to the step list 31_n are collectively referred to as step lists 31 in some cases below.

Note that the step list is associated with the substrate ID. Therefore, reading, writing, and the like of the step list are performed on the basis of the substrate ID in some cases.

In each of the step lists 31, a plurality of steps for manufacturing a semiconductor element are set in the order of manufacturing steps. Examples of the steps for manufacturing a semiconductor element include film deposition, cleaning, resist application, exposure to light, development, shaping, heat treatment, testing, and transfer of the substrate. Note that the number of steps may be the same or different among the step list 31_1 to the step list 31_n.

Note that an ID that is not the substrate ID may be assigned to each step. Here, the ID assigned to the step is expressed as a step ID.

Furthermore, processing conditions are designated for each of the steps set in the step lists 31. Examples of the processing conditions in the film deposition step include apparatus and settings such as temperature, pressure, power, and flow rate. Note that the processing conditions of the film deposition step influence the thickness, quality, and the like of a film deposited by the film deposition step, thereby influencing a characteristic value of the semiconductor element in some cases. Needless to say, processing conditions of steps other than the film deposition step, the presence or absence of steps, the order of steps, and the like can also influence the characteristic value of the semiconductor element.

The above-described processing conditions are selected from parameter sets (also referred to as major parameters or simply parameters) prepared in advance. Note that the parameters can be added later.

For example, processing conditions for a step are selecting from a plurality of parameters prepared in advance and designated. In other words, parameters are designated for the step.

Note that an ID that is not the substrate ID nor the step ID may be assigned to each of the parameters. Here, the ID assigned to the parameters is expressed as a parameter ID.

When planning the first lot 11, the user designates one substrate from n substrates (the substrate 21_1 to the substrate 21_n) prepared in the first lot 11. The designated substrate is expressed as a reference substrate 21R below. Note that the user does not necessarily designate the one substrate.

The above is the description of the structure of the first lot 11.

Next, the user implements the first lot 11. In other words, semiconductor elements are manufactured in accordance with the step lists prepared for the first lot 11.

Next, the user measures electrical characteristics of each of the manufactured semiconductor elements. For example, Id-Vg characteristics, from which temperature characteristics, a threshold voltage, or the like of a semiconductor element is evaluated, can be used for the electrical characteristics of the semiconductor elements.

Next, characteristic values are calculated from the measured electrical characteristics. Examples of the characteristic values include a threshold voltage (Vth), a subthreshold swing value (S value), an on-state current (Ion), and a field-effect mobility (μFE). The characteristic values calculated from the results of measuring electrical characteristics of the semiconductor elements are referred to as characteristic values of semiconductor elements or simply characteristic values below.

Regarding the semiconductor elements manufactured over the substrate 21_1 to the substrate 21_n, a characteristic value 61_1 to a characteristic value 61_n are calculated respectively. Note that the characteristic value 61_1 to the characteristic value 61_n each include the above-described characteristic value (any one or more of Vth, S value, Ion, μFE, and the like). For example, as illustrated in FIG. 2B, the characteristic value 61_1 of the semiconductor element manufactured over the substrate 21_1 includes a characteristic value 61_1(1) to a characteristic value 61_1 (q) (q is a natural number). Furthermore, each of the characteristic value 61_1(1) to the characteristic value 61_1 (q) includes characteristic values, the number of which is equal to or less than the number of semiconductor elements manufactured over the substrate 21_1. Note that the same applies to the characteristic value 61_2 to the characteristic value 61_n, a characteristic value 60_1 to a characteristic value 60_m described later, and the like. The characteristic values (the characteristic value 61_1 to the characteristic value 61_n) of the semiconductor elements manufactured over the substrates 21 are collectively expressed as the characteristic values 61 in some cases below.

Note that the characteristic value is associated with the substrate ID. Therefore, reading, writing, and the like of the characteristic value are performed on the basis of the substrate ID in some cases.

The above is the task performed by the user before Step S001. After the first lot 11 is implemented and the characteristic values 61 are calculated, the user inputs the step lists 31 and the characteristic values 61 of the semiconductor elements. After finishing the input, the process proceeds to Step S001.

<<Step S001>>

In Step S001, a step list 31R prepared for the reference substrate 21R and each of the steps lists prepared for the substrates included in the lot implemented in the past are compared. Note that subjects of the comparison of the step lists are steps and processing conditions (parameters) set in the step lists. The substrates included in the lot implemented in the past are collectively expressed as a group of substrates 20 (a substrate 20_1 to a substrate 20_m (m is a natural number)) below. The step lists prepared for the group of substrates 20 are collectively expressed as a group of step lists 30 (a step list 30_1 to a step list 30_m). The characteristic values of the semiconductor elements included in the group of substrates 20 are collectively expressed as a group of characteristic values 60 of the semiconductor elements or simply the group of characteristic values 60 (the characteristic value 60_1 to the characteristic value 60_m). In other words, Step S001 is a step of comparison between the step list 31R and the group of step lists 30.

First, a match/mismatch between the steps is checked. Note that in the case where IDs are assigned to the steps, the addition, deletion, or change of the step ID is checked. Alternatively, the steps may be all exported to text and a difference between character strings may be examined. Note that the step which is not directly concerned with the shape, structure, or the like of the semiconductor elements, such as testing or transfer of the substrate, may be excluded from the subjects of comparison. This can shorten the time necessary for the comparison.

In the case where the steps match each other, a match/mismatch between processing conditions (parameters) of the steps is checked. Note that in the case where IDs are assigned to the parameters, the addition, deletion, or change of the parameter ID is checked. Alternatively, the parameters may be all exported to text and a difference between character strings may be examined.

To check a match/mismatch between the steps and between the processing conditions (parameters) of the steps, a diff algorithm is used, for example.

In the comparison between the step list 31R and the group of step lists 30, a step list whose degree of similarity to the step list 31R is higher than or equal to a certain level can be collected from the group of step lists 30. In other words, Step S001 is a step for collecting a step list whose degree of similarity to the step list 31R is higher than or equal to a certain level from the group of step lists 30. In the case where a certain number or more of step lists whose degree of similarity is higher than or equal to a certain level are collected, a step list having the same degree of similarity (a step list which matches the step list 31R) or a step list having a higher degree of similarity may be extracted from the collected certain number or more of step lists. Here, the step list collected in Step S001 is expressed as a step list 35. The step list 35 is also a step list whose degree of similarity to the step list 31R is higher than or equal to a certain level. In other words, Step S001 is a step for obtaining the step list 35.

In the case where the reference substrate 21R is not designated, all the step lists 31 are compared with the group of step lists 30, and a step list whose degree of similarity to each of the step lists 31 is higher than or equal to a certain level can be collected from the group of step lists 30. In this case, the step list whose degree of similarity to each of the step lists 31 is higher than or equal to a certain level can be regarded as the step list 35.

In the case where one or more step lists whose degree of similarity is higher than or equal to a certain level or one or more step lists having the same degree of similarity or a higher degree of similarity are collected from the group of step lists 30, the process proceeds to Step S002.

<<Step S002>>

In Step S002, a test is performed using a characteristic value of the semiconductor element manufactured over the reference substrate 21R and a characteristic value of the semiconductor element manufactured over the substrate which is associated with the step list 35 by means of the substrate ID. Note that the step list and the characteristic value of the semiconductor element manufactured over the substrate which is associated with the step list by means of the substrate ID are associated by means of the substrate ID. The characteristic value of the semiconductor element manufactured over the reference substrate 21R is expressed as a characteristic value 61R below. The characteristic value of the semiconductor element manufactured over the substrate having the collected step list is simply expressed as the collected characteristic value, in some cases. The characteristic value of the semiconductor element manufactured over the substrate which is associated with the step list 35 by means of the substrate ID is expressed as a characteristic value 65. In other words, the characteristic value 65 is a characteristic value collected in Step S001.

The above-described test is performed using the characteristic value 61R and a characteristic value of the semiconductor element manufactured in accordance with the step list having the same degree of similarity or the highest degree of similarity among the step lists 35. Note that the test is not necessarily performed in that manner; the test may be performed using the characteristic value 61R and a plurality of characteristic values collected in Step 001. The test is performed per characteristic value.

In the above test, a t-test or the like is preferably used.

In the case where it is found as the result of the test that there is no significant difference between the characteristic value 61R and the characteristic value 65, the process proceeds to Step S003. In the case where it is found that there is a significant difference between the characteristic value 61R and the characteristic value 65, the first lot 11 may possibly have been implemented incorrectly. Thus, in the case where it is found that there is a significant difference, the user is notified to check whether the first lot 11 has been implemented correctly. After the notification is provided to the user, the process ends.

<<Step S003>>

In Step S003, analysis of variance is performed on the characteristic values 61 to find whether the step changed in the first lot 11 influences the characteristic value, and the presence or absence of the influence is recorded. First, among the substrates 21 included in the first lot 11, analysis of variance (also referred to as ANOVA) on the characteristic values 61 and comparison of the step lists 31 are performed. Note that the analysis of variance is performed per characteristic value.

For the above-described analysis of variance, Type 2 ANOVA, Type 3 ANOVA, a nonparametric test (the Kruskal-Wallis test or the Friedman test), or the like is used.

Before the analysis of variance is performed, statistical analysis may be performed. By the statistical analysis, a method used for the analysis of variance can be selected appropriately. As the statistical analysis, outlier detection, a test of normality of distribution, or a test of the equality of variances is performed, for example. In the case where the statistical analysis finds that the characteristic values 61 have no outlier or have normality of distribution or equality of variances, a parametric test is preferably selected for the analysis of variance. As the parametric test, Type 2 ANOVA is preferably used. This can improve the accuracy of analysis of variance.

In the case where the statistical analysis finds that the characteristic values 61 have an outlier or do not have normality of distribution or equality of variances, a nonparametric test is preferably selected for the analysis of variance. This can improve the accuracy of analysis of variance. Note that in the case where there is not a correspondence among the characteristic values 61 of the substrates 21, the Kruskal-Wallis test is used as the nonparametric test.

For the outlier detection, Local Outlier Factor or the like is used. Furthermore, as the test of normality of distribution, the Shapiro-Wilk test, the Kolmogorov-Smirnov test, or the like is used. In particular, the Shapiro-Wilk test is used. As the test of the equality of variances, the Levene's test, the Bartlett's test, the Hartley's test, or the like is used. In particular, the Levene's test is used.

The above-described analysis of variance can find whether there is a significant difference in characteristic values included in the characteristic values 61 (the characteristic value 61_1 to the characteristic value 61_n) among the substrates 21 (the substrate 21_1 to the substrate 21_n) included in the first lot 11.

Furthermore, the step lists 31 (the step list 31_1 to the step list 31_n) are compared between the substrates 21 (the substrate 21_1 to the substrate 21_n) included in the first lot 11, so that a step which is different among the substrates 21 can be extracted.

Note that subjects of the comparison of the step lists are, as described in <<Step S001>>, steps and processing conditions (parameters) set in the step lists. First, a match/mismatch between the steps is checked. In the case where the steps match each other, a match/mismatch between processing conditions (parameters) of the steps is checked. To check a match/mismatch between the steps and between the processing conditions (parameters) of the steps, a diff algorithm is used, for example.

In the case where the analysis of variance finds that one or more of the characteristic values 61 (the characteristic value 61_1 to the characteristic value 61_n) are significantly different among the substrates 21 (the substrate 21_1 to the substrate 21_n) included in the first lot 11, it is recorded that the step which is different among the substrates 21 significantly influences the characteristic value. The step whose significant influence on the characteristic value has been recorded is simply referred to as the step with an influence, in some cases below. Meanwhile, in the case where it is found that there is no significant difference among the characteristic values 61 of the substrates 21, it is recorded that the step which is different among the substrates 21 does not significantly influence the characteristic value.

Note that the characteristic values 61 (the characteristic value 61_1 to the characteristic value 61_n) may include a characteristic value which is found significantly different and a characteristic value which is found not significantly different among the substrates 21 (the substrate 21_1 to the substrate 21_n) included in the first lot 11. Thus, the presence or absence of the influence of the step which is different among the substrates 21 on the characteristic value may be recorded per characteristic value.

After the recording is finished, the process proceeds to Step S004.

<<Step S004>>

In Step S004, all the step lists 31 (the step list 31_1 to the step list 31_n) prepared for the substrates 21 (the substrate 21_1 to the substrate 21_n) included in the first lot 11 are compared with the group of step lists 30, and for each of the step lists 31, a step list which is different in only the step with an influence is collected from the group of step lists 30. Here, the step list collected in Step S004 is expressed as a step list 37. The step list 37 is also a step list which is different in only the step with an influence from the corresponding step list 31. In other words, Step S004 is a step for obtaining the step list 37.

Note that subjects of the comparison of the step lists are, as described in <<Step S001>>, steps and processing conditions (parameters) set in the step lists. First, a match/mismatch between the steps is checked. In the case where the steps match each other, a match/mismatch between processing conditions (parameters) of the steps is checked. To check a match/mismatch between the steps and between the processing conditions (parameters) of the steps, a diff algorithm is used, for example.

In the case where one or more step lists which are different from the corresponding step lists 31 in only the step with an influence are collected from the group of step lists 30, the process proceeds to Step S005. The characteristic value of the semiconductor element manufactured over the substrate which is associated with the step list 37 by means of the substrate ID is expressed as a characteristic value 67 below. In other words, the characteristic value 67 is a characteristic value collected in Step S004.

<<Step S005>>

In Step S005, machine learning based on parameters for the step with an influence and the characteristic value 67 is performed. For the machine learning, regression analysis is preferably used, for example. In this case, Step S005 is a step for performing regression analysis of the parameters for the step with an influence and the characteristic value 67. By using the regression analysis, a correlation between the parameters for the step with an influence and the characteristic value 67 can be analyzed. Thus, the characteristic value of the semiconductor element can be estimated.

Specifically, in the regression analysis in Step S005, the parameters for the step with an influence are used as explanatory variables, and the characteristic value 67 is used as an objective variable. For example, least squares linear regression is performed using the parameters for the step with an influence and the characteristic value 67.

Note that before the regression analysis, analysis of variance may be performed on the characteristic value 67 to check that the difference in the parameters for the step with an influence significantly influences the characteristic value. By checking the significance, the accuracy of the characteristic value of the semiconductor element estimated on the basis of the result of the regression analysis can be found high.

For the above-described analysis of variance, Type 2 ANOVA, Type 3 ANOVA, a nonparametric test (the Kruskal-Wallis test or the Friedman test), or the like is used.

Before the analysis of variance is performed, statistical analysis may be performed. By the statistical analysis, a method used for the analysis of variance can be selected appropriately. As the statistical analysis, outlier detection, a test of normality of distribution, or a test of the equality of variances is performed, for example. In the case where the statistical analysis finds that the characteristic value 67 has no outlier or has normality of distribution or equality of variances, a parametric test is preferably selected for the analysis of variance. As the parametric test, Type 2 ANOVA is preferably used. This can improve the accuracy of analysis of variance.

In the case where the statistical analysis finds that the characteristic value 67 has an outlier or does not have normality of distribution or equality of variances, a nonparametric test is preferably selected for the analysis of variance. This can improve the accuracy of analysis of variance. Note that in the case where there is not a correspondence among the characteristic values 67 of the substrates which are associated with the step lists 37 by means of the substrate IDs, the Kruskal-Wallis test is used as the nonparametric test.

For the outlier detection, Local Outlier Factor or the like is used. Furthermore, as the test of normality of distribution, the Shapiro-Wilk test, the Kolmogorov-Smirnov test, or the like is used. In particular, the Shapiro-Wilk test is used. As the test of the equality of variances, the Levene's test, the Bartlett's test, the Hartley's test, or the like is used. In particular, the Levene's test is used.

If the analysis of variance shows that the difference in the parameters for the step with an influence significantly influences the characteristic value, regression analysis of the parameters and the characteristic value is performed. By the regression analysis, the characteristic value of the semiconductor element can be estimated from the parameters.

For the regression analysis, linear regression, ridge regression, Lasso regression, elastic net, k-nearest neighbors algorithm, a regression tree, a random forest, support vector regression, a neural network, or the like can be used.

Although the method in which analysis of variance is performed before regression analysis is described above as an example, a correlation coefficient may be calculated by the regression analysis instead of the analysis of variance and used as a criterion for adopting the estimated value of the semiconductor element. As the correlation coefficient, the Pearson product-moment correlation coefficient, the Spearman's rank correlation coefficient, the Kendall rank correlation coefficient, or the like can be used.

In the above-described manner, the characteristic value of the semiconductor element can be estimated from the step with an influence and the parameters for the step.

Note that after Step S005 is finished, the step lists 31 and the characteristic values 61 are stored in the group of step lists 30 and the group of characteristic values 60, respectively. The storage may also be performed after Step S006 is finished.

The above is the description of Step S005.

Next, as the task performed by the user before Step S006, the user plans a second lot 12. Note that the second lot 12 is not necessarily planned after the implementation of Step S005. The user may plan the second lot 12 before the start of Step S001 or during the implementation of Step S001 to Step S005.

After the second lot 12 is planned, the process proceeds to Step S006.

<<Step S006>>

In Step S006, characteristic values 62 are estimated from step lists 32 on the basis of the result of the regression analysis performed in Step S005. Then, the estimated characteristic values 62 are output. In other words, Step S006 is a step for estimating the characteristic values 62 and outputting the estimated characteristic values 62. Here, the step lists 32 are step lists prepared for the second lot 12. Furthermore, the characteristic values 62 are characteristic values of semiconductor elements to be manufactured in accordance with the step lists 32.

Note that what is output is not limited to the estimated characteristic values 62. For example, in the case where only the steps without an influence are different among the step lists 32 prepared for substrates 22 included in the second lot 12, the user may be notified of information that the difference in the characteristic value 62 will be small among the substrates 22. Furthermore, the user may be notified of information regarding which step in a step list 32R that is prepared for a reference substrate 22R designated in the second lot 12 influences the characteristic value 62.

After the estimated characteristic values 62 are output or after the user is notified of the information, the process ends.

By implementing Step S001 to Step S006, a characteristic value of a semiconductor element can be estimated without manufacturing the semiconductor element or measuring electrical characteristics of the semiconductor element. Accordingly, the number of times a semiconductor element is prototyped can be reduced, reducing development costs and shortening the development period, for example.

Furthermore, by the method for estimating a characteristic value of a semiconductor element, which is described in this section, data such as characteristic values, step lists, and parameters for steps are appropriately associated and accumulated. As the data is accumulated more, the ability of estimating the characteristic value is improved, and the characteristic value can be estimated with high accuracy. When the second lot 12 is planned, the step lists 32 are automatically compared with the group of step lists 30; therefore, the user can analyze the data from a bird's eye view.

The above is the description of an example of the method for estimating a characteristic value of a semiconductor element.

### Procedure Example

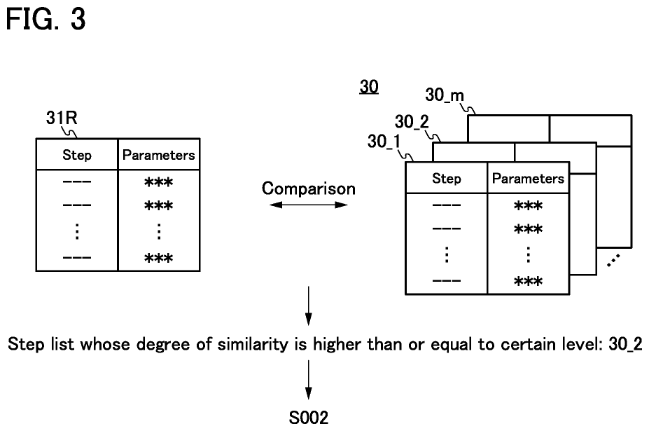

In this section, examples of Step S001 to Step S006 which are described in <Procedure> above are described with reference to FIG. 3 to FIG. 8.

FIG. 3 is a diagram illustrating an example of Step S001.

In Step S001, as described above, the step list 31R is compared with the group of step lists 30. For example, in FIG. 3, a step list 30_2 among the step list 30_1 to the step list 30_m is assumed to be a step list whose degree of similarity to the step list 31R is higher than or equal to a certain level. At this time, the step list 30_2 is collected. Note that the step list 30_2 illustrated in FIG. 3 corresponds to the step list 35 described in <Procedure> above. Then, the process proceeds to Step S002.

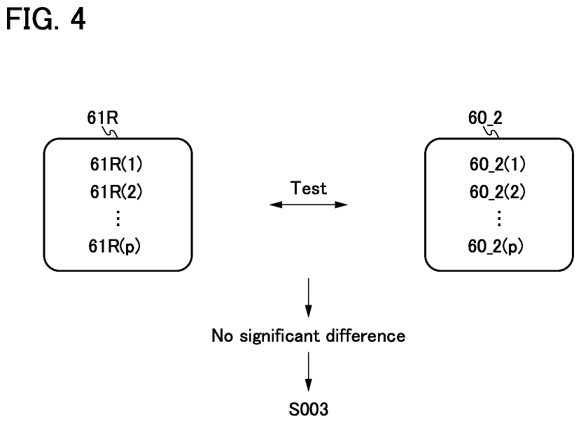

FIG. 4 is a diagram illustrating an example of Step S002.

In Step S002, as described above, a test is performed using the characteristic value 61R and the characteristic value 65.

In FIG. 4, in the case where the substrate IDs are assigned, a characteristic value 60_2 is extracted from the group of characteristic values 60 on the basis of the substrate ID associated with the step list 30_2 collected in Step S001, for example. Note that the characteristic value 60_2 illustrated in FIG. 4 corresponds to the characteristic value 65 described in <Procedure> above. The test is performed using the characteristic value 61R (a characteristic value 61R(1) to a characteristic value 61R(p)) and the characteristic value 60_2 (a characteristic value 60_2(1) to a characteristic value 60_2(p)). In the case where the test finds that there is no significant difference between the characteristic value 61R and the characteristic value 60_2, the process proceeds to Step S003.

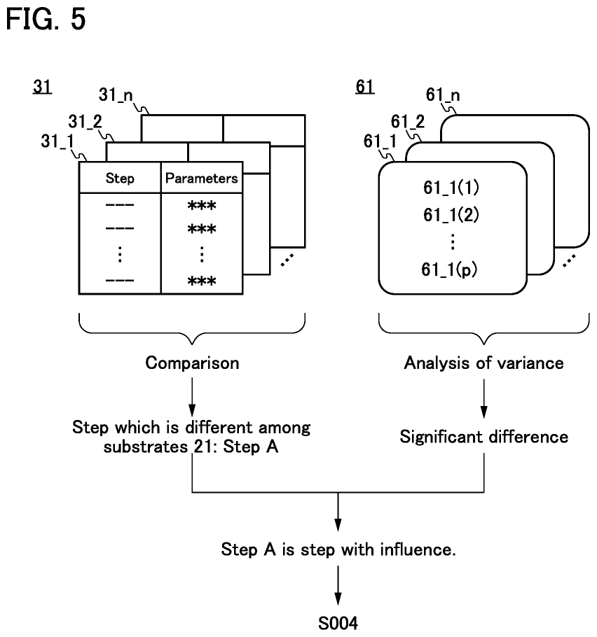

FIG. 5 is a diagram illustrating an example of Step S003.

In Step S003, as described above, among the substrates 21, analysis of variance on the characteristic values 61 and comparison of the step lists 31 are performed. For example, in FIG. 5, the comparison of the step lists 31 (the step list 31_1 to the step list 31_n) among the substrates 21 finds that the step which is different among the substrates 21 is Step A. Although an example where the step which is different among the substrates 21 is Step A is illustrated in FIG. 5, there may be two or more steps which are different among the substrates 21.

Furthermore, for example, in FIG. 5, the analysis of variance on the characteristic values 61 (the characteristic value 61_1 to the characteristic value 61_n) among the substrates 21 finds that there is a significant difference among the characteristic values included in the characteristic values 61. In this case, after it is recorded that Step A is a step with an influence, the process proceeds to Step S004.

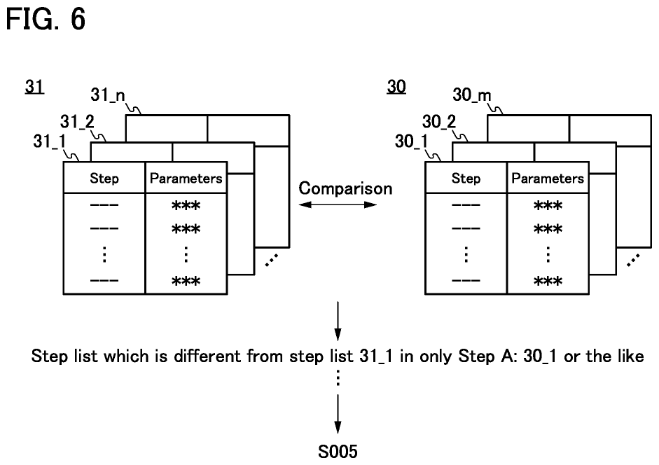

FIG. 6 is a diagram illustrating an example of Step S004.

In Step S004, as described above, all the step lists 31 are compared with the group of step lists 30, and for each of the step lists 31, a step list which is different in only the step with an influence is collected from the group of step lists 30. For example, through the comparison in FIG. 6, the step list 30_1 or the like is collected as the step list which is different from the step list 31_1 in only Step A. Here, the step list 30_1 or the like corresponds to the step list 37 described in <Procedure> above. Note that collection of the step list which is different in only Step A is performed also for each of the step list 31_2 to the step list 31_n. Then, the process proceeds to Step S005.

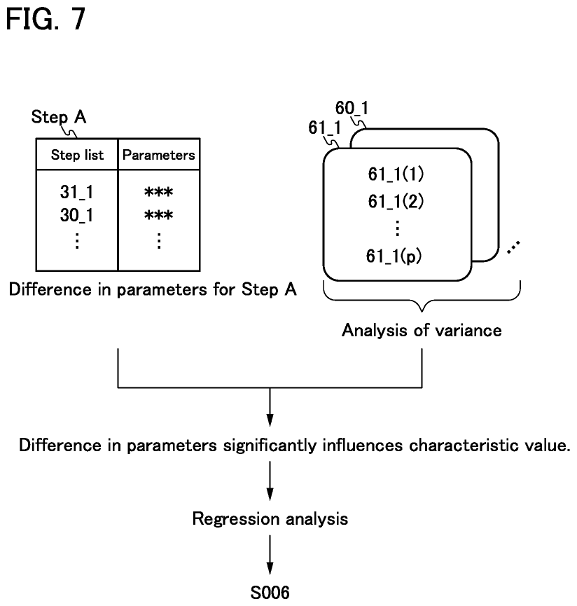

FIG. 7 is a diagram illustrating an example of Step S005.

In Step S005, regression analysis of the parameters for the step with an influence and the characteristic value 67 is performed as described above. In FIG. 7, the characteristic value 67 is a characteristic value of a semiconductor element manufactured over a substrate associated with the step list 30_1 or the like collected in Step S004 by means of the substrate ID. In other words, the characteristic value 67 is the characteristic value 60_1 or the like. For example, it is identified by the analysis of variance in FIG. 7 that the difference in the parameters for Step A of the step list 31_1 significantly influences the characteristic value. In this case, regression analysis of the parameters for Step A and characteristic values such as the characteristic value 61_1 and the characteristic value 60_1 is performed. Then, the process proceeds to Step S006.

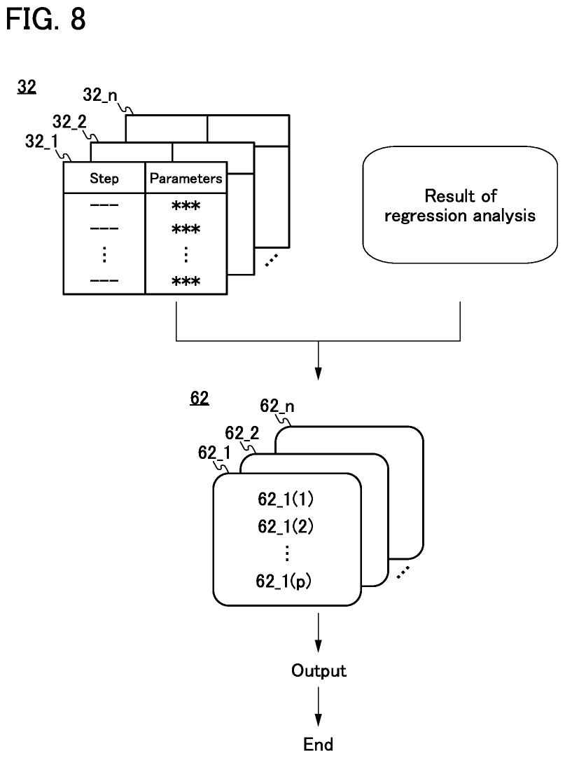

FIG. 8 is a diagram illustrating an example of Step S006.

In Step S006, as described above, the characteristic values 62 are estimated from the step lists 32 on the basis of the result of the regression analysis performed in Step S005. For example, in FIG. 8, the characteristic values 62 (a characteristic value 62_1 to a characteristic value 62_n) are estimated from the step lists 32 (a step list 32_1 to a step list 32_n) on the basis of the result of the regression analysis performed in Step S005. After the estimated characteristic values 62 are output, the process ends.

The above is the description of examples of Step S001 to Step S006.

<Structure Example of System>

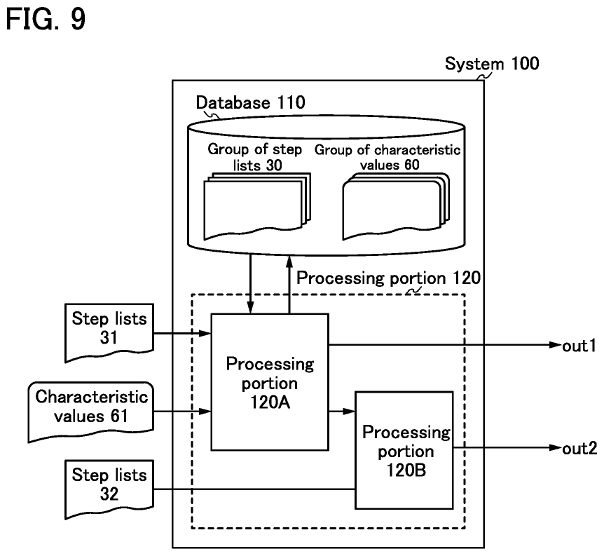

In this section, a structure example of the system which estimates a characteristic value of a semiconductor element, which is one embodiment of the present invention, is described with reference to FIG. 9.

FIG. 9 is a diagram illustrating a structure example of a system 100 which can estimate a characteristic value of a semiconductor element. The system 100 includes an input portion (not illustrated in FIG. 9), a database 110, and a processing portion 120. Note that the database 110 and the processing portion 120 are connected via a network. Note that examples of the network include a local area network (LAN), the Internet, and the like. In addition, either one or both of wired and wireless communications can be used for the network.

The step lists 31, the step lists 32, and the characteristic values 61 are input to the input portion.

In the database 110, the group of step lists 30 prepared for the group of substrates 20 and the group of characteristic values 60 that the group of substrates 20 has are stored.

The processing portion 120 includes a processing portion 120A and a processing portion 120B.

The step lists 31 and the characteristic values 61 are input to the processing portion 120A through the input portion. Furthermore, the group of step lists 30 and the group of characteristic values 60 which are stored in the database 110 are input to the processing portion 120A.

The processing portion 120A has a function of handling Step S001 to Step S005 described above. Specifically, the processing portion 120A has a function of performing comparison between two step lists, a function of performing a test using two or more characteristic values of semiconductor elements, and a function of performing regression analysis of parameters for a step and two or more characteristic values of semiconductor elements. Note that the test involves analysis of variance. Furthermore, the processing portion 120A may have a function of performing statistical analysis.

The two step lists are selected from the step lists 31 input through the input portion and the group of step lists 30 stored in the database 110. The two or more characteristic values of semiconductor elements are selected from the characteristic values 61 of semiconductor elements input through the input portion and the group of characteristic values 60 of semiconductor elements stored in the database 110. Note that, in some cases, the two or more characteristic values of semiconductor elements used for the test and the two or more characteristic values of semiconductor elements used for the regression analysis are not the same.

Moreover, the processing portion 120A may have a function of outputting out1. Here, out1 is information for notifying the user to check whether the first lot has been correctly implemented. The output of the information enables the user to know that the first lot might not have been implemented correctly, without comparing the first lot with the previous lot.

The step lists 32 are input to the processing portion 120B through the input portion. The result of the regression analysis performed in the processing portion 120A is input to the processing portion 120B.

The processing portion 120B has a function of handling Step S006 described above. Specifically, the processing portion 120B has a function of estimating the characteristic values 62 from the step lists 32 input through the input portion.

Furthermore, the processing portion 120B has a function of outputting out2. Here, out2 is the estimated characteristic values 62 or the information described in <<Step S006>>.

With the above-described structure, the system 100 capable of estimating a characteristic value of a semiconductor element can be provided. With the system 100, data such as characteristic values, step lists, and parameters for steps are appropriately associated and accumulated. As the data is accumulated more, the ability of estimating the characteristic value is improved, and the characteristic value can be estimated with high accuracy. When the second lot 12 is planned, the step lists 32 are automatically compared with the group of step lists 30; therefore, the user can analyze the data from a bird's eye view.

<Detailed Structure Example of System>

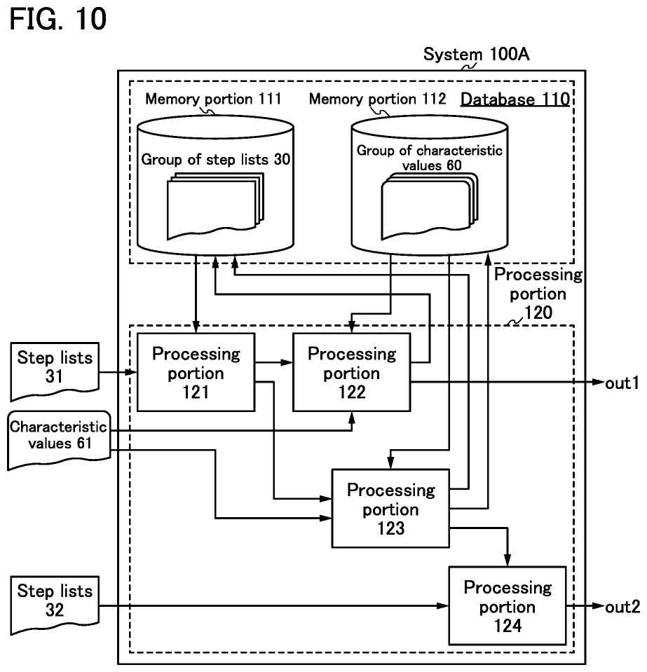

In this section, details of the structure example of the system 100, which is one embodiment of the present invention, are described with reference to FIG. 10. Unless otherwise described, the description of components of the system 100, functions of the components, and the like can be referred to for components of the system, functions of the components, and the like described in this section below.

FIG. 10 is a diagram illustrating a system 100A which can estimate a characteristic value of a semiconductor element. Note that the system 100A is the details of the structure of the system 100 illustrated in FIG. 9. Like the system 100, the system 100A includes the input portion (not illustrated in FIG. 10), the database 110, and the processing portion 120. Note that the database 110 includes a memory portion 111 and a memory portion 112. Furthermore, the processing portion 120 includes a processing portion 121 to a processing portion 124.

<<Memory Portion 111>>

The group of step lists 30 is stored in the memory portion 111. Furthermore, parameter sets prepared in advance are stored in the memory portion 111. Note that the step which is different among the substrates 21 and the presence or absence of the influence on the characteristic values 61, which are described in <<Step S003>>, may be recorded in the memory portion 111.

<<Memory Portion 112>>

The group of characteristic values 60 is stored in the memory portion 112.

<<Processing Portion 121>>

The step lists 31 and the group of step lists 30 are input to the processing portion 121.

The processing portion 121 has a function of comparing step lists. For the comparison of step lists, a diff algorithm is preferably used as described above. The diff algorithm is preferably stored in a memory portion (not illustrated in FIG. 10) included in the processing portion 121. In the case where the diff algorithm is stored in the memory portion 111 or the like, the diff algorithm is preferably supplied from the memory portion 111 or the like to the processing portion 121.

For example, the processing portion 121 can compare the step list 31R with the group of step lists 30 as described in <<Step S001>>. The processing portion 121 collects a step list whose degree of similarity to the step list 31R is higher than or equal to a certain level from the group of step lists 30. Then, the processing portion 121 outputs the collected step list or the substrate ID associated with the collected step list to the processing portion 122. The step list output to the processing portion 122 corresponds to the step list 35 described in <<Step S001>>.

For example, the processing portion 121 can compare the step lists 31 among the substrates 21 included in the first lot 11 as described in <<Step S003>>. The processing portion 121 extracts a step which is different among the substrates 21. Then, the processing portion 121 outputs the step which is different among the substrates 21 or the step ID of the step to the processing portion 122.

Furthermore, for example, the processing portion 121 can compare the step lists 31 with the group of step lists 30 as described in <<Step S004>>. For each of the step lists 31, the processing portion 121 collects a step list which is different in only the step with an influence from the group of step lists 30. Then, the processing portion 121 outputs the collected step list or the substrate ID associated with the collected step list to the processing portion 123. The step list output to the processing portion 123 corresponds to the step list 37 described in <<Step S004>>.

<<Processing Portion 122>>

The characteristic values 61 are input to the processing portion 122. In addition, the step list or the substrate ID associated with the step list, which is output from the processing portion 121, is input. Furthermore, the step which is different among the substrates 21 or the step ID of the step, which is output from the processing portion 121, is input.

The processing portion 122 has a function of collecting a characteristic value corresponding to the above-described step list or the above-described substrate ID from the group of characteristic values 60. Note that the group of characteristic values 60 may be input to the processing portion 122 and a characteristic value corresponding to the above-described step list or the above-described substrate ID may be extracted from the group of characteristic values 60.

Furthermore, the processing portion 122 has a function of performing a test on a characteristic value. Note that the test involves analysis of variance. In addition, the processing portion 122 has a function of outputting out1. Furthermore, the processing portion 122 may have a function of performing statistical analysis. Note that an algorithm of analysis of variance, statistical analysis, or the like is preferably stored in a memory portion (not illustrated in FIG. 10) included in the processing portion 122. Alternatively, in the case where the algorithm of analysis of variance, statistical analysis, or the like is stored in the memory portion 112 or the like, the algorithm of analysis of variance, statistical analysis, or the like is preferably supplied from the memory portion 112 or the like to the processing portion 122.

For example, the processing portion 122 can perform a test using the characteristic value 61R and the characteristic value collected in Step S001 as described in <<Step S002>>. In the case where it is found as the result of the test that there is a significant difference, the processing portion 122 outputs out1. Note that the characteristic value collected in Step S001 corresponds to the characteristic value 65 described in <<Step S002>>, and out1 is information of which the user is notified described in <<Step S002>>.

In the case where it is found as the result of the test that there is no significant difference, the processing portion 122 can perform analysis of variance described in <<Step S003>>. At this time, the processing portion 122 has a function of outputting the presence or absence of the influence of the step which is different among the substrates 21 on the characteristic value to the memory portion 111. Note that the processing portion 122 may perform statistical analysis described in <<Step S003>>.

<<Processing Portion 123>>

The characteristic values 61 are input to the processing portion 123. In addition, the step list or the substrate ID associated with the step list, which is output from the processing portion 121, is input.

The processing portion 123 has a function of collecting a characteristic value corresponding to the above-described step list or the above-described substrate ID from the group of characteristic values 60. Note that the group of characteristic values 60 may be input to the processing portion 123 and a characteristic value corresponding to the above-described step list or the above-described substrate ID may be extracted from the group of characteristic values 60.

The processing portion 123 has a function of performing regression analysis of parameters for a step with an influence and a characteristic value as described in <<Step S005>>. Furthermore, the processing portion 123 has a function of outputting a result of the regression analysis to the processing portion 124. In addition, the processing portion 123 has a function of outputting the step lists 31 to the memory portion 111. Moreover, the processing portion 123 has a function of outputting the characteristic values 61 to the memory portion 112. Note that an algorithm of regression analysis is preferably stored in a memory portion (not illustrated in FIG. 10) included in the processing portion 123. Alternatively, in the case where the algorithm of regression analysis is stored in the memory portion 112 or the like, the algorithm of regression analysis is preferably supplied from the memory portion 112 or the like to the processing portion 123.

Note that the processing portion 123 may have a function of performing a test on characteristic values. Note that the test involves analysis of variance. Furthermore, the processing portion 123 may have a function of performing statistical analysis. In the case where the processing portion 123 does not have the function of performing a test on characteristic values and the function of performing statistical analysis, the analysis of variance and the statistical analysis, which are described in <<Step S005>>, are preferably performed in the processing portion 122. Note that arrows indicating the input/output of data, an instruction, or the like between the processing portion 122 and the processing portion 123 are not illustrated in FIG. 10.

<<Processing Portion 124>>

The step lists 32 are input to the processing portion 124. In addition, the result of regression analysis, which is output from the processing portion 123, is input.

The processing portion 124 has a function of estimating characteristic values from the step lists 32 using the result of the regression analysis. The processing portion 124 has a function of outputting out2. The characteristic values estimated from the step lists 32 correspond to the characteristic values 62 described in <<Step S006>>, and out2 is the estimated characteristic values or information or the like of which the user is notified described in <<Step S006>>.

Until the step lists 32 are input to the processing portion 124, the result of the regression analysis performed in the processing portion 123 is preferably kept stored in a temporary memory area included in the processing portion 123 or the processing portion 124. Alternatively, the result of the regression analysis performed in the processing portion 123 may be stored in the memory portion 111 or the like and may be input to the processing portion 124 at the time when the step lists 32 are input to the processing portion 124.

With this structure, a system which can estimate a characteristic value of a semiconductor element can be provided.

<Variation of System>

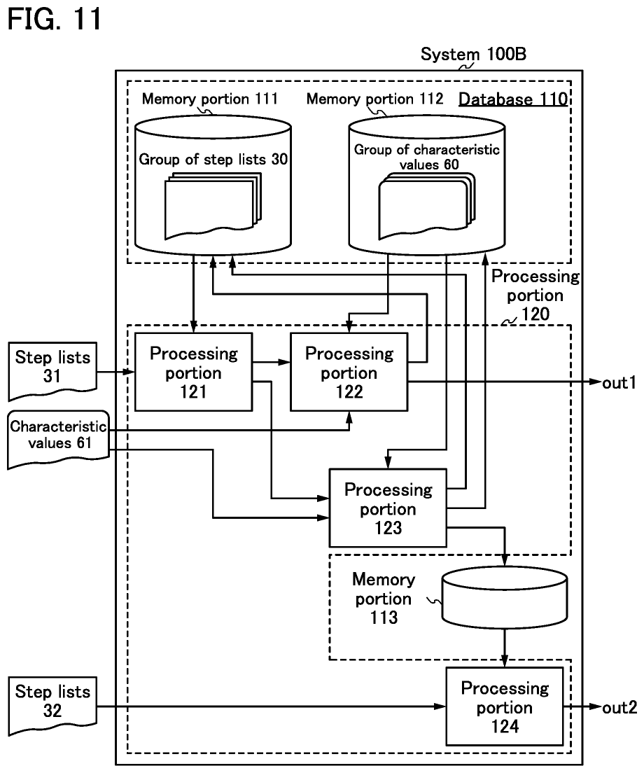

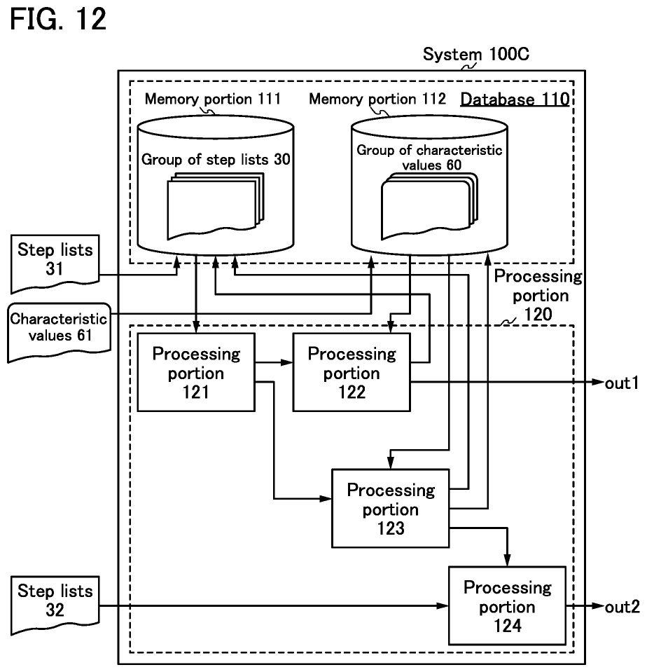

The structure example of the system which estimates a characteristic value of a semiconductor element is not limited to the structure of the system 100A illustrated in FIG. 10. Variations of the system which estimates a characteristic value of a semiconductor element are described below with reference to FIG. 11 and FIG. 12.

<<Variation 1 of System>>

FIG. 11 is a diagram illustrating a structure example of a system 100B. Note that components of the system 100B illustrated in FIG. 11 having the same functions as those of the system described in <Structure example of system> and <Detailed structure example of system> are denoted by the same reference numerals.

The system 100B illustrated in FIG. 11 is a variation of the system 100A illustrated in FIG. 10. The system 100B is different from the system 100A in including a memory portion 113.

In the memory portion 113, the result of the regression analysis performed in the processing portion 123 is stored, whereby the system 100B can be kept in a standby state until the step lists 32 are input.

<<Variation 2 of System>>

FIG. 12 is a diagram illustrating a structure example of a system 100C. Note that components of the system 100C illustrated in FIG. 12 having the same functions as those of the system described in <Structure example of system> and <Detailed structure example of system> are denoted by the same reference numerals.

The system 100C illustrated in FIG. 12 is a variation of the system 100A illustrated in FIG. 10. The system 100C is different from the system 100A in that the step lists 31 are stored in the memory portion 111 and the characteristic values 61 are stored in the memory portion 112 before Step S001 to Step S006 described above are implemented.

With the above-described structure, step lists and characteristic values of the implemented lots are sequentially stored in the database; therefore, the system 100C can be used even if the first lot 11 is not planned and implemented before the second lot 12 is planned. In other words, the above-described task performed by the user before Step S001 may be omitted.

For example, a step list that a substrate serving as a reference substrate has is selected from the group of step lists 30. Next, a step list whose degree of similarity to the selected step list is higher than or equal to a certain level is collected from the group of step lists 30 through the processing portion 121. The collected step list and the selected step list may be regarded as the step list prepared for the first lot 11 and the step list 31R, respectively, in using the system 100C. Thus, the system 100C can be utilized even if the first lot 11 is not planned and implemented.

<Computer Device>

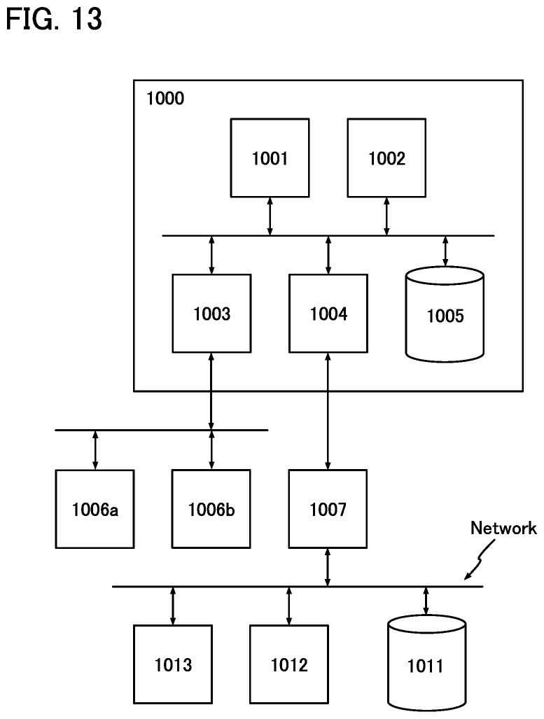

In this section, a computer device including the system which estimates a characteristic value of a semiconductor element, which is one embodiment of the present invention, is described with reference to FIG. 13.

FIG. 13 is a diagram illustrating the computer device including the system which estimates a characteristic value of a semiconductor element. A computer device 1000 is connected to a database 1011, a remote computer 1012, and a remote computer 1013 via a network. The computer device 1000 includes an arithmetic device 1001, a memory 1002, an input/output interface 1003, a communication device 1004, and a storage 1005. The computer device 1000 is electrically connected to a display device 1006a and a keyboard 1006b through the input/output interface 1003. In addition, the computer device 1000 is electrically connected to a network interface 1007 through the communication device 1004, and the network interface 1007 is electrically connected to the database 1011, the remote computer 1012, and the remote computer 1013 through the network (Network).

Here, examples of the network include a local area network (LAN), the Internet, and the like. In addition, either one or both of wired and wireless communications can be used for the network. Furthermore, in the case where a wireless communication is used for the network, besides near field communication means such as Wi-Fi (registered trademark) and Bluetooth (registered trademark), a variety of communication means such as the third generation mobile communication system (3G)-compatible communication means, LTE (sometimes also referred to as 3.9G)-compatible communication means, the fourth generation mobile communication system (4G)-compatible communication means, or the fifth generation mobile communication system (5G)-compatible communication means can be used.

In the system which estimates a characteristic value of a semiconductor element, which is one embodiment of the present invention, the database 110 corresponds to the database 1011. Note that the database 110 may be the storage 1005. Furthermore, the step lists 31 and the characteristic values 61 may be stored in the storage 1005 at first and may be stored in the database 1011 after Step S005 described above is completed.

Furthermore, the processing portion 120 corresponds to the arithmetic device 1001. Note that the processing portion 120 may be an arithmetic device included in the remote computer 1012 or the remote computer 1013. Moreover, the processing portion 121 to the processing portion 123 included in the processing portion 120 may be an arithmetic device included in the remote computer 1012 or the remote computer 1013, and the processing portion 124 included in the processing portion 120 may be the arithmetic device 1001.

The above-described out1 and out2 are displayed on the display device 1006a. Note that the display device 1006a may display a result of the comparison between step lists, a result of the test, a result of the analysis of variance, a result of the statistical analysis, and the like in the form of a table, a numerical formula, a graph, and the like, for example.

According to the above description, one embodiment of the present invention can provide a method for estimating a characteristic value of a semiconductor element to be prototyped. Furthermore, one embodiment of the present invention can provide a system which estimates a characteristic value of a semiconductor element to be prototyped. Moreover, one embodiment of the present invention can provide a system which automatically compares steps and a characteristic value of a semiconductor element prototyped this time with those of a previously prototyped semiconductor element.

Parts of this embodiment can be combined as appropriate for implementation.

### REFERENCE NUMERALS

11: first lot, 12: second lot, 20: group of substrates, 20_m: substrate, 20_1: substrate, 21: substrate, 21_n: substrate, 21_1: substrate, 21R: reference substrate, 22: substrate, 22R: reference substrate, 30: group of step lists, 30_m: step list, 30_1: step list, 30_2: step list, 31: step list, 31_n: step list, 31_1: step list, 31_2: step list, 31R: step list, 32: step list, 32_n: step list, 32_1: step list, 32R: step list, 35: step list, 37: step list, 60: group of characteristic values, 60_m: characteristic value, 60_1: characteristic value, 60_2: characteristic value, 61: characteristic value, 61_n: characteristic value, 61_1: characteristic value, 61_2: characteristic value, 61R: characteristic value, 62: characteristic value, 62_n: characteristic value, 62_1: characteristic value, 65: characteristic value, 67: characteristic value, 100: system, 100A: system, 100B: system, 100C: system, 110: database, 111: memory portion, 112: memory portion, 113: memory portion, 120: processing portion, 120A: processing portion, 120B: processing portion, 121: processing portion, 122: processing portion, 123: processing portion, 124: processing portion, 1000: computer device, 1001: arithmetic device, 1002: memory, 1003: input/output interface, 1004: communication device, 1005: storage, 1006a: display device, 1006b: keyboard, 1007: network interface, 1011: database, 1012: remote computer, 1013: remote computer

1. A semiconductor element characteristic value estimation system comprising:
an input portion;
a database; and
a processing portion,
wherein a first step list, a second step list, and a characteristic value of a semiconductor element are input to the input portion,
wherein the database is configured to store a group of step lists and a group of characteristic values of semiconductor elements,
wherein the processing portion is configured to perform comparison between two step lists selected from the first step list and the group of step lists,
wherein the processing portion is configured to perform a test using two or more characteristic values of semiconductor elements selected from the characteristic value of the semiconductor element and the group of characteristic values of the semiconductor elements,
wherein the processing portion is configured to perform regression analysis of parameters for a step and two or more characteristic values of semiconductor elements selected from the characteristic value of the semiconductor element and the group of characteristic values of the semiconductor elements, and
wherein the processing portion is configured to estimate a characteristic value of a semiconductor element from the second step list.

2. The semiconductor element characteristic value estimation system according to claim 1,
wherein a diff algorithm is used in the comparison, and
wherein in the test, a t-test is used as a test using two characteristic values of semiconductor elements and a nonparametric test is used as a test using three or more characteristic values of semiconductor elements.

3. The semiconductor element characteristic value estimation system according to claim 1,
wherein the database comprises a first memory portion and a second memory portion,
wherein the first memory portion has a function of storing the group of step lists, and
wherein the second memory portion has a function of storing the group of characteristic values of the semiconductor elements.

4. The semiconductor element characteristic value estimation system according to claim 1,
wherein the processing portion comprises:
a first processing portion having a function of performing the comparison;
a second processing portion having a function of performing the test;
a third processing portion having a function of performing the regression analysis; and
a fourth processing portion having a function of estimating a characteristic value of a semiconductor element from the second step list.

5. The semiconductor element characteristic value estimation system according to claim 1,
wherein the characteristic value of the semiconductor element estimated by the processing portion is one or more of a threshold voltage, a subthreshold swing value, an on-state current, and a field-effect mobility.

6. A semiconductor element characteristic value estimation method comprising:
a first step of inputting a first step list included in a first lot and a characteristic value of a first semiconductor element manufactured in accordance with the first step list;
a second step of collecting a second step list whose degree of similarity to the first step list is higher than or equal to a certain level from a group of step lists;
a third step of performing a test using the characteristic value of the first semiconductor element and a characteristic value of a second semiconductor element manufactured in accordance with the second step list;
a fourth step of performing, among a first plurality of semiconductor elements manufactured in accordance with a first plurality of step lists included in the first lot, analysis of variance on characteristic values of the first plurality of semiconductor elements and comparison of the first plurality of step lists and recording whether a step which is different among the first plurality of step lists influences the characteristic values of the first plurality of semiconductor elements;
a fifth step of collecting a third step list whose degree of similarity to each of the first plurality of step lists is higher than or equal to a certain level from the group of step lists;
a sixth step of performing regression analysis of parameters for a step influencing the characteristic values of the first plurality of semiconductor elements and a characteristic value of a third semiconductor element manufactured in accordance with the third step list; and
a seventh step of estimating, from a second plurality of step lists included in a second lot, characteristic values of a second plurality of semiconductor elements manufactured in accordance with the second plurality of step lists before the second plurality of semiconductor elements are manufactured.

7. The semiconductor element characteristic value estimation method according to claim 6,
wherein data is output in the case where there is a significant difference between the characteristic value of the first semiconductor element and the characteristic value of the second semiconductor element in the test performed in the third step.
